(19) United States
(12) Patent Application Publication
(10) Pub. No.: US 2018/0128647 A1
(43) Pub. Date: May 10, 2018

(54) DEVICE AND METHOD TO CONTROL THE UNIFORMITY OF A GAS FLOW IN A CVD OR AN ALD REACTOR OR OF A LAYER GROWN THEREIN

(71) Applicant: AIXTRON SE, Herzogenrath (DE)

(72) Inventors: Gi Youl Kim, San Jose, CA (US); Mark Chen-Lun Lin, San Jose, CA (US); Gregory Siu, Saratoga, CA (US); Ki Chul Park, Hwasung (KR); Jonathan David Mohn, Saratoga, CA (US); H. William Luca, JR., Watsonville, CA (US)

(21) Appl. No.: 15/348,883

(22) Filed: Nov. 10, 2016

(51) Int. Cl. G01D 5/10; C23C 16/52; C23C 16/455

(52) U.S. Cl. CPC G01D 5/10; C23C 16/45544; C23C 16/52

(57) ABSTRACT

A measuring device is provided for determining the position of a susceptor in a reactor housing. The measuring device includes a central element, which can be fastened on the susceptor at a predefined location, and a plurality of sensing arms, which protrude from the central element beyond an outer periphery of the susceptor. The sensing arms respectively include a sensing section that can be brought in touching contact with a contact zone. The contact zone is formed by an inner periphery of the reactor housing or a component arranged in the reactor housing. Using the measuring device, the position of a susceptor of a CVD reactor is determined relative to the reactor housing or a component arranged in the reactor housing.

### TECHNICAL FIELD

The invention pertains to a measuring device, by means of which the position of a susceptor in a reactor housing of an ALD/CVD reactor can be determined.

The invention furthermore pertains to a method for adjusting the position of a susceptor relative to the reactor housing or a component arranged in the reactor housing.

### PRIOR ART

U.S. Pat. No. 8,398,777 B2 and US 2016/0010239 A1 describe CVD reactors with a susceptor that is arranged in a reactor housing, into which process gases can be introduced, such that one or more layers can be grown on at least one substrate lying on the susceptor. The lateral position of the susceptor can be adjusted by means of an adjusting device.

In CVD reactors known from the prior art, e.g. from U.S. Pat. No. 6,767,429 B2, U.S. Pat. No. 7,648,610 B2, US 2012/0024479 A1 or U.S. Pat. No. 6,963,043 B2, a susceptor with a supporting surface for one or more substrates is located in a process chamber, wherein the gas discharge surface of a gas inlet element lies opposite of the supporting surface. The outer peripheral edge of the essentially annular susceptor is surrounded by an annular flow-through area, wherein the flow-through area extends from the outer peripheral edge of the susceptor to an inner peripheral edge of a component surrounding the susceptor or the housing wall surrounding the susceptor. A process gas, which is introduced into the process chamber continuously or in the form of gas pulses through the gas discharge surface of the gas inlet element frequently realized in the form of a showerhead, causes the growth of a layer on the substrate, namely either due to a physical change in the state of aggregation or due to a chemical reaction. Reaction products or a carrier gas, which does not participate in the layer growth, are discharged from the process chamber into a downstream volume of the reactor housing through the flow-through area. A pipe system connects a gas suction opening arranged at this location to a vacuum pump, by means of which the reactor housing can be evacuated or by means of which a stationary total pressure can be adjusted within the reactor housing and, in particular, within the process chamber. Due to the asymmetric arrangement of the gas suction opening, a non-symmetric flow profile forms within the volume of the reactor housing arranged downstream of the flow-through opening such that the gas flow passing through the flow-through area is not homogenous in the circumferential direction of the flow-through area. Due to the inhomogeneous discharge of the process gas from the process chamber, an asymmetric flow profile also forms within the process chamber and results in a non-homogenous growth of the layers to be grown.

The above-cited prior art already discloses measures for influencing the flow profile within the process chamber by utilizing perforated plates or by changing the radial width of the flow-through area.

### SUMMARY OF THE INVENTION

An object of the invention is to develop a device which can optimize the uniformity of layer grown on one or more substrates located on a susceptor. A further object of the invention is developing a measuring device, by means of which the position of the susceptor within the reactor housing can be determined, wherein the position determination can effectively be carried out in-situ while the reactor housing is closed or as the reactor housing is closed.

A first aspect of the invention pertains to a measuring device for determining the position of the susceptor in the reactor housing, wherein the measuring device features a central element that can be fastened on the susceptor at a predetermined location, e.g. in a center of the susceptor. Several sensing arms are arranged on the central element and protrude over the outer periphery of the susceptor. On their free ends, these sensing arms feature sensing sections that can be brought in contact with a contact zone of the reactor housing, wherein this contact zone may be formed by an inner periphery of the reactor housing, by a component within the reactor housing or by a periphery of a component within the reactor housing. The contact zone is preferably realized in the region of an upper part of the reactor housing, which can be separated from a lower part of the reactor housing in order to open the reactor housing. It is particularly proposed that the measuring device can be attached to the susceptor while the reactor housing is opened, wherein a centering pin can engage into a centering opening such that the measuring device, particularly its central element, assumes a predefined position relative to the susceptor. The one or more sensing arms feature sensing sections, which can be brought in touching contact with the contact zone. Spring elements are provided and act upon the sensing arms in the direction extending away from the central element. In this way, the spring elements acting upon the one or more sensing arms displace the sensing sections into their position, in which they are spaced apart from the center by the maximum distance. The sensing sections may have sloping flanks. As the reactor housing is closed, a peripheral edge of the reactor housing or a component arranged in the reactor can act upon the sloping flank of the sensing arm or the sensing section in such a way that the sensing arm is displaced in the direction of the central element against the restoring force of the spring element. The spring element therefore exerts a contact pressure that presses the sensing section of the sensing arm against one of several contact zones of the reactor housing. A position-measuring element makes it possible to determine the radial distance of the sensing section from the central element and, in particular, from the center of the susceptor. It is particularly proposed that the central element features a plurality of sensing arms, preferably four sensing arms that protrude from the central element in uniform angular distribution and respectively feature a sensing section that can be brought in contact with an inner periphery of a component or the reactor housing, such that the radial distance of the inner periphery of the component or the reactor housing from the center of the susceptor can be determined in a plurality of circumferential positions. The measuring device features a data transmission unit, by means of which the measured values can be wirelessly transmitted to an external receiver through the process chamber wall. A battery is provided for the energy supply. In a variation of the invention, the susceptor has a circular outer periphery, in the center of which the central element of the measuring device can be arranged. The inner periphery of the component or the reactor housing is radially spaced apart from the outer periphery of the susceptor by a gap width that is dependent on the position of the susceptor, wherein the inner periphery extends radially outside the outer periphery. The inner periphery preferably extends along a circular arc such that a flow-through area in the form of an area extending parallel to the upper side of the susceptor carrying the substrates is formed between the inner periphery and the outer periphery of the susceptor. In a few embodiments of the invention, the flow-through area is a uniform, continuous area that completely surrounds the susceptor. The flow-through area forms in a few embodiments of the invention an annular gap that is defined by an inner periphery and an outer periphery. In a few embodiments of the invention, the susceptor is carried by a susceptor carrier featuring a first flange with a first flange face, which is arranged displaceably along a second flange face of a second flange. In this case, the second flange is rigidly connected to the reactor housing. The adjusting means feature setscrews in a few embodiments of the invention. The position of the susceptor within the reactor housing can be adjusted by turning the setscrew, wherein the adjusting direction is a plane, in which the flow-through area extends. In this case, the setscrews are screwed into threaded bores in one of the two flanges. The setscrews are preferably screwed into a threaded bore in the first flange. An end face of the setscrew acts upon the other flange, particularly the second flange. In a few embodiments, springs are provided and acted upon by the setscrews. It is particularly proposed that the setscrews are arranged on one of the two flanges, which respectively have a circular outline, in order to adjust the first flange relative to the second flange in two directions of the adjustment plane extending perpendicular to one another. Each setscrew may be opposed by a spring with a sufficiently high spring force for displacing the first flange relative to the second flange when the setscrew is turned in the loosening direction. A few embodiments of the invention may feature a bellows, by means of which the susceptor carrier is connected to the reactor housing. It is particularly proposed that the first fastening end of the bellows is connected to a collar of the susceptor carrier, and that a second fastening end of the bellows is connected to the second flange. The two connections are preferably gastight. In a few embodiments, the measuring device features one or more spring elements, wherein one of the spring elements acts upon the sensing arm in the direction extending away from the central element. In addition, a radial distance of the sensing section of the sensing arm may be determined by means of a position-measuring element. The sensing element or another section of the sensing arm may furthermore have a sloping flank. The reactor housing may feature a lower part, to which the susceptor is assigned. The reactor housing may also feature an upper part, to which the gas inlet element is assigned. In a variation of the invention, the upper part can be separated from the lower part in order to open the process chamber. Flushing gas openings are provided and arranged in a wall of a flushing gas duct surrounding the gas inlet element. The susceptor has a center axis, in which the susceptor carrier is preferably arranged. The susceptor is annularly surrounded by the flow-through area referred to the center axis. The radial width of the flushing gas duct referred to the center axis approximately corresponds to the radial width of the flow-through area, which simultaneously represents the gap width. The flushing gas discharged from the flushing gas openings of the flushing gas duct upstream of the flow-through area mixes with the process gas introduced into the process chamber through the gas discharge openings of the gas inlet element.

The invention furthermore pertains to a method for determining the lateral position of the susceptor in the reactor housing and/or for varying the gap width of the flow-through area by varying the position of the susceptor within the reactor housing, wherein the above-described measuring device, which is attached to the susceptor after the reactor housing has been opened and once again removed from the reactor housing after the position of the susceptor has been adjusted, particularly is used in said method. The position determination and the adjustment of the susceptor position respectively take place while the reactor housing is closed. The adjustment of the position is realized by adjusting the adjusting means at lowered process chamber pressures. The determination of the lateral position of the susceptor within the reactor housing may also take place as the reactor housing is closed by attaching an upper part of the housing to a lower part of the housing. The upper part of the housing features a contact zone that is scanned by the measuring device. The contact zone is preferably scanned by the sensing sections of the sensing arms of the measuring device attached to the susceptor. The sensing sections preferably have sloping flanks that are acted upon by the contact zone when the upper part of the reactor housing is attached to the lower part of the reactor housing. The central element of the measuring device is fastened on the susceptor in a centered fashion such that the arms are displaced in the direction of the center against the restoring force of a spring element. During the attachment of the upper reactor part, the inner periphery of the reactor housing forming the contact zone or the component fastened on the upper reactor part can pass over the sloping flank such that the peripheral edge of the sloping flank abuts on the contact zone. The peripheral edge may extend on the surface area of a cylinder. The measured values recorded by the measuring device are wirelessly transmitted to a receiver arranged outside the reactor housing through the wall of the process chamber housing. The measuring device features a battering housing fitted with batteries for its energy supply. The inventive method makes it possible to adjust the susceptor into an exactly central position relative to the housing wall or components arranged in the housing. However, it is also possible to purposefully adjust the susceptor into an eccentric position in order to counteract the influences on the gas flow in the susceptor, which cause an eccentrically arranged gas outlet opening. The position of the susceptor can also be adjusted while a layer is grown on substrates carried by the susceptor. The adjustment may take place at a low pressure and an elevated temperature. The determination of the lateral position of the susceptor or the adjustment of the position of the susceptor for optimizing the gas flow above the susceptor is preferably realized without optical sensors.

A further object of the invention is maximizing the uniformity of a gas flow above the susceptor or the uniformity of the physical or chemical properties of a layer grown on substrates located on the susceptor. The method comprises a plurality of consecutive steps wherein in each step one or more substrates are coated with a layer, wherein after each coating step the position of the susceptor is varied, wherein the lateral position of the susceptor is determined with the above-mentioned method. A further object of the invention is to maximize the uniformity by feeding a flushing gas especially Ar or N₂ through a flushing gas opening into the process chamber wherein the flushing gas opening is preferably located in flow direction above the flow-through area. A variation of the invention is to vary the heating power of two heating elements for heating the susceptor in a way that the uniformity is maximized. In order to maximize the uniformity of a grown layer, it is particularly proposed to initially pre-adjust the position of the susceptor while the process chamber is open, for example when a cover of the process chamber is removed, wherein the effects of the eccentric position of a gas discharge opening arranged downstream of the flow-through opening on the flow field upstream of the susceptor particularly are also taken into account in this case. According to the invention, other adjusting steps can be carried out after such an initial adjusting step, wherein these adjusting steps are preferably carried out while the process chamber is closed.

In the first adjusting step, the susceptor position is adjusted in such a way that the influences of an eccentrically arranged gas discharge opening downstream of the flow-through area on the flow field around the susceptor are compensated. This is realized by varying the position of the susceptor in the plane of the flow-through area such that the radial width of the flow-through area changes. This may be carried out while the process chamber is open. A precision adjustment of the susceptor position takes place in a second adjusting step, in which the susceptor is closed and under growth conditions. The process chamber is at the process temperature. A process pressure is adjusted within the process chamber. The process temperature is an elevated temperature. It may amount to several 100° C. The total pressure in the process chamber is a low pressure, for example a pressure of a few mbar. Under these growth conditions, a layer can be grown on a substrate or on several substrates arranged in the process chamber. In a preferred embodiment of the invention, the reactor housing features means for measuring the layer thickness of the grown layer in situ and/or means for determining the layer composition in situ at different locations and, in particular, at different circumferential positions on the periphery of the susceptor. Optical sensors particularly are used for this purpose. If a non-uniform layer composition or layer thickness is detected, a gas flow that influences a layer property such as, for example, the layer thickness and/or the layer composition can be changed by varying the position of the susceptor. For example, if a comparatively great layer thickness is measured at a three o'clock position, the susceptor can be shifted in the direction of the nine o'clock position in order to thereby influence the gas flow around the susceptor. A variation of the cross section of the flow-through area influences the flow rate of the gas flow that flows over the substrate at this location. This method for determining the layer properties and for subsequently adjusting the position of the susceptor can be repeated in several successive steps. It is advantageous that this position adjustment of the susceptor can be carried out under process conditions without having to lower the process temperature or raise the process pressure. The position adjustment of the susceptor essentially takes place without interruption as the result of a variation of a total pressure or a temperature such that a position adjustment can be carried out within a short period of time. In an enhancement of the invention, it is proposed to carry out a third adjusting step, in which a precision adjustment of the layer growth is likewise realized by influencing a flow, particularly after the second adjusting step. In this third adjusting step, the aforementioned flushing gas flows into the flow-through area are influenced at different circumferential positions. In this case, a precision adjustment of the flushing gas flows is also carried out under growth conditions, i.e. under growth temperature and total growth pressure. The flushing gas flows are varied in dependence on the in situ measurement of a layer property such as the layer thickness and/or layer composition. In an enhancement of the invention, the lateral layer homogeneity can be maximized with a fourth adjusting step. The heating device arranged underneath the susceptor features two or more radially nested heaters that can be controlled separately of one another. The layer growth rate in a radially outer zone can be reduced by reducing the heating power at this location. An increase of the heating power in the outer heating zones makes it possible to increase the growth rate of the grown layer at these locations.

### BRIEF DESCRIPTION OF THE DRAWINGS

The invention is described in greater detail below with reference to exemplary embodiments. In the drawings:

FIG. 1 schematically shows a longitudinal section through a reactor housing 1,

FIG. 2 shows an enlarged detail of FIG. 1, in which a measuring device 25 is attached to a susceptor 3,

FIG. 3 shows a section along the line III-III in FIG. 2,

FIG. 4 shows a longitudinal section through a second exemplary embodiment of a process chamber of a closed reactor housing 1, the upper part of which can be separated from a lower part in the direction of the arrow P in order to open the reactor housing,

FIG. 5 shows a perspective view of a measuring device arranged on a susceptor, and

FIG. 6 schematically shows a longitudinal section through a sensing arm 29, which is fastened on a central element 26 of the measuring device and features a sensing end 30.

### DESCRIPTION OF THE EMBODIMENTS

A reactor housing 1 consists of a gastight steel housing such that the volume of the housing 1 can be evacuated. An upper housing part 1′ can be separated from and, in particular, lifted off a lower housing part 1″ in order to open a process chamber 9 of the reactor housing 1.

A gas inlet element 6 designed in the form of a showerhead is fastened on the upper housing part 1′. It features a gas discharge surface with a plurality of gas discharge openings 7 for introducing a process gas into the process chamber 9. The process gas may consist of a carrier gas that transports reactive gases. The carrier gas may consist of a noble gas. However, hydrogen or nitrogen may also be considered as carrier gases. The carrier gas particularly transports volatile source materials that contain metals in order to grow TiSiN layers, LaOx, ZrOx, HfOx or underdoped “high-K” layers on a substrate 5. The flow rates of the carrier gases and the source materials are adjusted by means of a not-shown mass flow controller. The gas flows being discharged from the gas discharge openings 7 flow over the substrate 5 lying on a susceptor 3 in a radial direction referred to the center of the circular, disk-shaped susceptor 3.

The outer periphery 4 of the susceptor 3 is surrounded by a gap that extends along a circle and has a gap width S. The gap width S may vary at different circumferential positions if the outer periphery of the susceptor 3 does not extend concentric to a circular inner periphery 2 of the reactor housing 1. The inner periphery 2 does not necessarily have to be formed by the reactor housing 1, but may also be formed by a component 21 arranged within the reactor housing (see FIG. 4). The gap between the inner periphery 2 and the outer periphery of the susceptor 3 forms a flow-through area 10, through which the process gas can flow from the process chamber 9 into a housing section 11 arranged downstream of the process chamber 9. A gas suction opening 8 is arranged at this location in an eccentric position and connected to a not-shown gas suction line that in turn is connected to a vacuum pump, by means of which the hollow space of the reactor housing 1 can be evacuated or by means of which a defined total pressure can be adjusted within the process chamber 9.

The susceptor 3 is carried by a susceptor carrier 12 that is connected to a first flange 13. A second flange face 14′ of a second flange 14 abuts on a first flange face 13′ of the first flange 13. The first flange 13 is rigidly connected to the susceptor 3 whereas the second flange 14 is rigidly connected to the reactor housing 1. The two flanges 13, 14 can be displaced relative to one another with the aid of adjusting means. The plane flange faces 13′, 14′ slide on one another during this displacement. Consequently, the susceptor 3 can be displaced within the plane, in which the flow-through area 10 lies. For this purpose, the flange faces 13′, 14′ respectively extend parallel to the direction, in which the flow-through area 10 extends, and parallel to the upper side of the susceptor 3, which carries the at least one substrate 5 and in turn extends parallel to the gas discharge surface of the gas inlet element 6.

The flanges 13, 14 can be displaced relative to one another in the two directions, in which the flange faces 13′, 14′ extend, by means of several setscrews 16. Four setscrews 16 may be provided, wherein two setscrews 16 respectively lie opposite of one another in a square arrangement. The setscrews 16 have a fine-pitch thread and are respectively screwed into threaded bores 36. In this case, the threaded bores 36 may be arranged in a collar, which protrudes from the outer periphery of the first flange 13 in the direction of the second flange 14, such that the collar forms a border, near which the second flange 14 is located.

In a variation of the invention, however, it is proposed that two setscrews 16, which can be respectively actuated in directions extending perpendicular to one another, are provided and a spring element 23 is arranged opposite of each of these setscrews 16. The second flange 14 can be displaced relative to the first flange 13 against the restoring force of the spring element 23 by turning the setscrew 16 in one direction. If the setscrews 16 is turned in the opposite direction, the spring force of the spring element 23 causes a displacement of the second flange 14 in the opposite direction. The spring element 23 may be arranged in a bore of the collar and supported on a circumferential area of the second flange 14. In an opposite location of the circumferential area, an end face 16′ of the setscrew 16 acts upon the circumferential periphery of the second flange 14.

A bellows 15 is provided and fastened on the reactor housing 1 with a fastening element and on the susceptor 3 with its second fastening end. For this purpose, the susceptor carrier 12 features in the exemplary embodiment a collar 24, on which the fastening element of the bellows 15 is fastened. The other fastening element of the bellows is fastened on the flange 14 on the housing side.

A flushing gas duct 17 is located vertically above the flow-through area 10 in a region radially outside the process chamber 9. The flushing gas duct 17 features a plurality of circumferentially arranged gas discharge openings 18, through which a flushing gas can be directly introduced into the flow-through area 10. The flushing gas openings 18 are located on a circular, arc-shaped line in the flow direction, namely above and approximately in the center of the continuous circular, arc-shaped flow-through area 10, such that the process gas discharged from the gas discharge openings 7 is mixed with the flushing gas radially outside the process chamber.

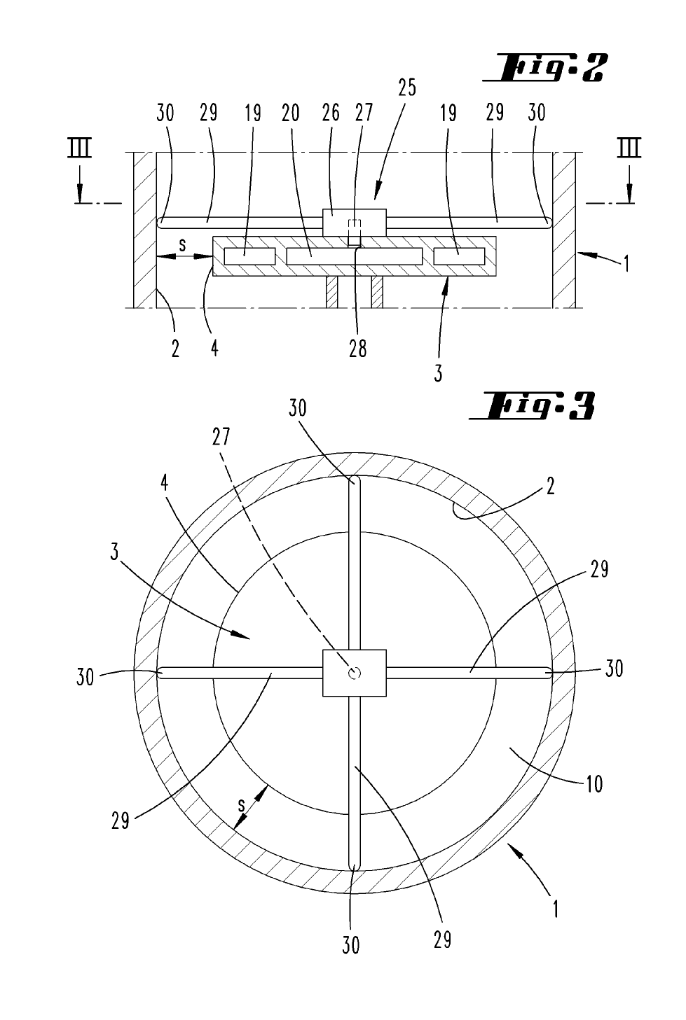

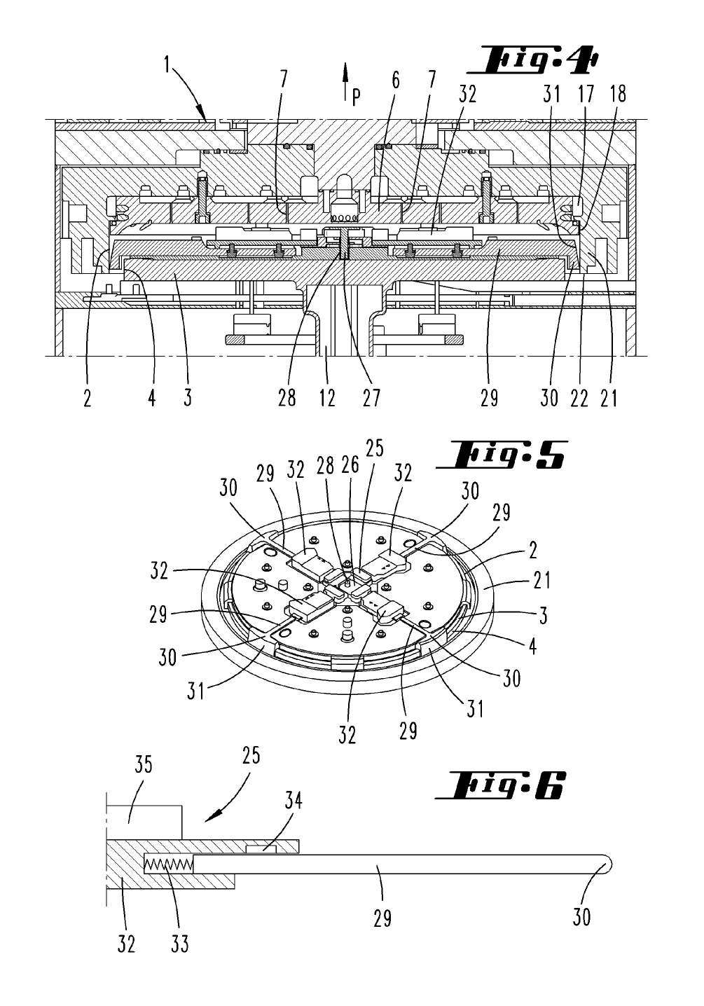

FIGS. 2 and 3 schematically show a measuring device 25, by means of which the relative position of the susceptor 3 within the process chamber 1 can be determined. The measuring device 25 particularly makes it possible to determine the gap width S of the flow-through area 10 at different circumferential positions. The gap width S extends in the radial direction and defines the distance between the outer periphery 4 of the susceptor 3 and the inner periphery 2 of the reactor housing 1 or of a component 21 that is arranged in the reactor housing 1 and annularly surrounds the susceptor 3 (see FIG. 4).

The measuring device 25 features a central element 26 that can be temporarily fastened on the susceptor 3 with the aid of fastening means. In the exemplary embodiment, the fastening means consist of centering elements. The centering elements in the exemplary embodiment consist of a centering pin 27 that is inserted into a centering opening 28.

Several sensing arms 29, which feature sensing sections 30 on their ends, protrude from the central element 26 in uniform circumferential distribution. In the exemplary embodiment, four sensing arms 29 protrude from the central element 26. The sensing arms 29 are preferably spring-loaded in the radial direction such that the sensing sections 30 abut on the inner periphery 2 under the influence of a spring force.

FIG. 6 schematically shows the corresponding design of the measuring device 25. The central element 26 features a measuring unit with an opening, in which one end of the sensing arm 29 is arranged. A spring element 33 acts upon the end of the sensing arm 29 in the radial direction, i.e. away from the central element 26.

A position-measuring element 34 is provided, by means of which the radial position of the sensing arm 29 relative to the central element 26 can be determined.

A communication device 35 is capable of communicating wirelessly with a not-shown transceiver. The communication device 35 features its own power supply, e.g. in the form of a battery. The communication device 35 can transmit the radial positions of the sensing arms 29 to the not-shown transceiver. It is particularly proposed that the reactor housing 1 features zones of dielectric material, through which the wireless data transmission link extends. The measuring device features a battery compartment with batteries arranged therein for its energy supply. The battery compartment may be assigned to the central element 26.

In the exemplary embodiment illustrated in FIG. 4, the sensing arm 29, particularly the sensing section 30, has a sloping flank 31. The component 21 surrounding the susceptor 3, which is rigidly connected to the reactor housing 1, has a peripheral edge 22 that acts upon the sloping flank 31 as the housing is closed opposite to the direction of the arrow P in FIG. 4 such that the sensing arm 29 can be moved into its scanning position. The sloping flanks 31 are acted upon by the peripheral edge 22 in a direction extending perpendicular to the direction, in which the sensing arm 29 extends, such that the sensing arm 29 is displaced in the direction of the center, in which the centering pin 27 is located. The peripheral edge 22 passes over the sloping flank 31 such that a periphery of the sloping flank 31 abuts on a contact zone of the component 21. The periphery of the sloping flank 31 may extend on the surface area of a cylinder.

The position-measuring elements 34 measure the radial distance of the sensing section 30 from the center of the susceptor 3 and therefore the local gap width S. The radial position of the susceptor 3 within the reactor housing 1 and therefore the local gap width S can be adjusted with the aid of the adjusting means 13, 14, 16.

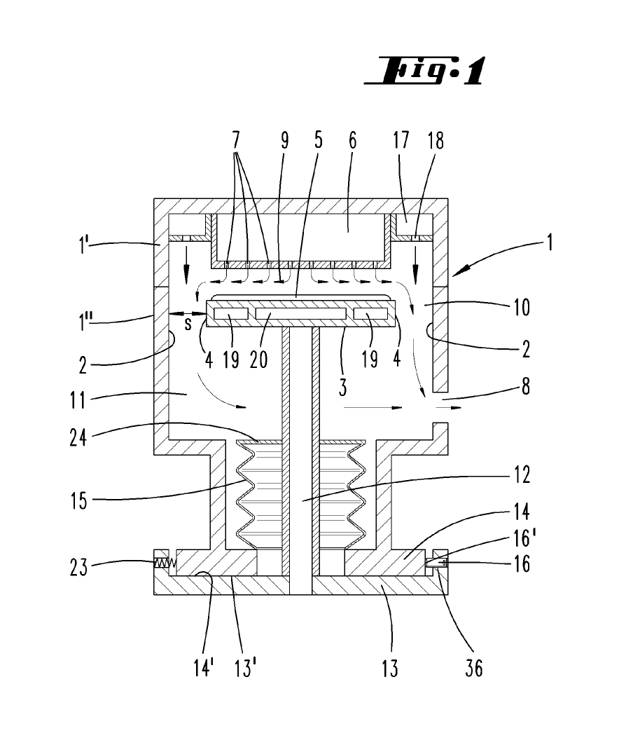

The gap width S influences the gas flow from the gas inlet element 6 over the substrate 5 and into the housing volume 11, which is arranged underneath the susceptor 3 and contains the gas suction opening 8, wherein this gas flow is indicated with arrows in FIG. 1. Due to the eccentric position of the gas suction opening 8, an asymmetric gas flow—referred to the axis of the susceptor 3—forms within the gas volume 11. The flow resistance of the flow-through area 10 can be locally influenced by laterally adjusting the position of the susceptor 3 and thereby varying the gap width S. The optimal position of the susceptor 3 can be determined in the closed state of the reactor housing 1 and under process pressures by means of an iteration method. Since the adjusting means feature screws 16 with a fine-pitch thread, an in-situ adjustment in the micrometer range can be realized.

According to another aspect of the invention, the gas flow in the process chamber 9 above the susceptor 3 can also be influenced by varying the flushing gas flows introduced through the flushing gas opening 18. It is particularly proposed that an overall Ar flow of 100 SCCM to 7000 SCCM flows through these flushing gas openings 18. Preferably the flow can be in a range between 500 SCCM and 4900 SCCM. Alternatively, N2 may also be used as flushing gas instead of Ar.

The flow profile can likewise be influenced due to the utilization of two heating elements 19, 20 at different radial distances from the center of the susceptor, wherein the heating elements 19, 20 are respectively supplied with different power. For this purpose, the susceptor features hollow spaces, in which a radially inner heating element 20 and a radially outer healing element 19 surrounding the inner heating element are arranged.

A circumferentially symmetric layer can be grown on the substrate 5 due to the utilization of the measuring device 25 in combination with the adjusting means 13, 14, 16. The gap width S is optimized in order to achieve this azimuthal symmetry. A radially symmetric layer profile can be adjusted between the center of the substrate 5 and its outer periphery 4 with the aid of the two heating devices 19, 20. For example, if the layer thickness in the peripheral region needs to be increased, the radially outer heating device 19 is supplied with greater heating power such that the process temperature is locally increased. The layer growth can be supplementally influenced by introducing a flushing gas through the peripheral flushing gas openings 18. The introduction of a flushing gas flow makes it possible to grow layers, the layer thickness of which is thinner in the peripheral region. This is a result of the dilution effect achieved by introducing the flushing gas.

A layer can be grown on an individual substrate 5 on the non-rotating susceptor 3. This layer is then analyzed with respect to its layer composition and its layer thickness. The result of this analysis makes it possible to deduce the direction, in which the susceptor 3 has to be adjusted within the reactor housing 1 with the aid of the adjusting means 13, 14, 16 in order to compensate asymmetries or inhomogeneities detected during the analysis. The respective heating power for operating the heating devices 19, 20, as well as the flushing gas flow through the flushing gas openings 18, is likewise optimized based on these analyses.

However, an optimization of the local gap width S based on the position of the susceptor 3 relative to the reactor housing 1 can also be realized with several substrates that are merely arranged on the peripheral region of the susceptor 3. In the iterative method, a layer is initially grown on the at least one substrate and its layer properties are analyzed, particularly in the peripheral region, in several steps. The direction, in which the susceptor 3 has to be displaced within the reactor housing 1 in order to locally vary the gap width S of the flow-through area 10 in such a way that the layer properties homogenize, is then determined based on a model calculation or experiences gained otherwise. The position of the susceptor 3 can be adjusted in a reproducible fashion due to the utilization of the described measuring device 25.

The invention pertains to a method for optimizing the uniformity of a layer grown on one or more substrates lying on the susceptor 3. In this case, the uniformity concerns the layer thickness. However, it may also concern the layer composition. In a first adjusting step, the position of the susceptor 3 is adjusted while the process chamber is open. A precision adjustment of the position of the susceptor 3 is carried out in one or more adjusting steps while the process chamber is closed. In a second adjusting step, the position of the susceptor particularly is varied within the inner periphery 2 of the reactor housing 1 or of a component arranged in the reactor housing. This takes place under process conditions, e.g. at a total pressure within the process chamber that is lowered to the process pressure and while the susceptor 3 is heated to a process temperature. Optical sensors that are not illustrated in the drawings particularly may be provided within the reactor housing 1 in order to measure the layer thickness of a layer grown on a substrate 5 arranged on the susceptor 3 on the periphery of the susceptor. This may be realized, for example, by means of an interferometer. The layer composition can be determined by means of photoluminescence measurements. A non-uniform layer growth can be detected by measuring one or more of these layer properties at different circumferential positions. A subsequent displacement of the susceptor 3 within the flow-through area 10 makes it possible to influence the flow through the flow-through area 10 in such a way that the layer growth is reduced at locations, at which an excessive layer growth was detected. This is achieved, for example, by increasing the gap width of the flow-through area 10 at this location.

The second adjusting step is successively repeated several times until the uniformity of the layer composition can no longer be maximized with this method. In this case, a layer property such as, for example, the layer thickness is initially measured at different circumferential positions of the susceptor and the position of the susceptor 3 is then suitably varied.

Non-uniformities of the layer property, e.g. the layer thickness, can be additionally compensated by carrying out a third adjusting step, in which the layer property, e.g. the layer thickness, is initially also determined at different circumferential positions and a flushing gas flow is subsequently varied at different circumferential positions such that the layer property changes at these locations during the growth of a layer. If the layer property is a layer thickness, for example, the flushing gas flow is varied at one or more circumferential positions in such a way that the layer growth is increased or decreased. An increase of the flushing gas flow at a certain circumferential position leads to a reduced layer growth rate at this location. A reduction of the flushing gas flow in turn leads to an increase of the growth rate at this location.

In a fourth adjusting step, the heating power of a radially outer heater 19 can be modified. The layer growth is reduced in a radially outer region by reducing the heating power of the radially outer heater 19. The layer growth is in turn increased by increasing the heating power of the radially outer heater 19.

The second to fourth adjusting steps, which respectively consist of a measuring step and an adjusting step, respectively can be successively repeated several times, wherein the process chamber temperature and the process chamber pressure are not changed.

The preceding explanations serve for elucidating all inventions that are included in this application and respectively enhance the prior art independently with at least the following combinations of characteristics, namely:

A device, which is characterized by adjusting means 13, 14, 16 for varying the position of the susceptor 3 relative to the reactor housing 1 or the component 21 and to thereby vary the distance S between the outer periphery 4 and the inner periphery 2, and by a measuring device 25 for determining the position of the susceptor 3 relative to the inner periphery 2′.

A device, which is characterized in that the flow-through area 10 is an annular gap surrounding the susceptor 3.

A device, which is characterized in that a susceptor carrier 12 carrying the susceptor 3 features a first flange 13 with a first flange face 13′ and a second flange 14 with a second flange face 14′ is arranged on the reactor housing 1, wherein the first flange 13 is displaceably connected to the second flange 14, and wherein the first flange face 13′ slides along the second flange face 14′ during a displacement of the first flange 13 relative to the second flange 14.

A device, which is characterized in that the adjusting means feature one or more setscrews 16, which are respectively screwed into a threaded bore in the first flange 13 and engage on the second flange 14 with an end face 16′.

A device, which is characterized in that one or more of the setscrews 16 act against a spring 23, which supports the second flange 14 relative to the first flange 13.

A device, which is characterized in that the susceptor carrier 12 is connected to a first end of a bellows 15, the second end of which is connected to the reactor housing 1.

A device, which is characterized by flushing gas openings 18 for introducing a flushing gas into the flow-through area 10, wherein the flushing gas openings 18 are arranged upstream of the flow-through area 10 in such a way that a process gas, which is introduced into a process chamber arranged above the susceptor 3 through a gas inlet element 6, mixes with the flushing gas in the flow-through area 10.

A device, which is characterized in that the susceptor 3 features a radially inner heating element 20 and a radially outer heating element 19 surrounding the inner heating element.

A measuring device, which is characterized by the determination of the position of a susceptor 3 in a reactor housing 1, featuring a central element 26, which can be fastened on the susceptor 3 at a predefined location, and a plurality of sensing arms 29, which protrude from the central element 26 beyond an outer periphery 4 of the susceptor 3, wherein said sensing arms respectively feature a sensing section 30 that can be brought in touching contact with a contact zone.

A measuring device, which is characterized in that the contact zone is formed by an inner periphery 2 of the reactor housing 1 or a component 21 arranged in the reactor housing 1.

A measuring device, which is characterized in that the central element 26 features centering means 27, 28, by means of which the central element 26 can be fastened in the center of the susceptor 3.

A measuring device, which is characterized in that the measuring device features communication means for the wireless data exchange through the wall of the reactor housing 1.

A measuring device, which is characterized in that the measuring device features a battery.

A measuring device, which is characterized in that the sensing arms 29 are acted upon in the direction extending away from the central element 26 by a spring element 33.

A measuring device, which is characterized by a position-measuring element 34 for determining the position of the sensing arm 29 relative to the central element 26.

A measuring device, which is characterized in that the position-measuring element 34 determines the distances of the sensing sections 30 from a center of the measuring device.

A measuring device, which is characterized in that the sensing section 30 has a sloping flank 31.

A measuring device, which is characterized in that the sloping flanks 31 of the sensing sections 30 are arranged in such a way that they are acted upon by the inner periphery 2 of the reactor housing 1 or by the component 21 arranged in the reactor housing 1 as the opened reactor housing 1 is closed and the sensing arms 29 are displaced toward a center of the susceptor 3 due to a sliding motion of the inner periphery 2 of the reactor housing 1 or the component 21 along the sloping flanks 31, wherein the distance of the sensing section 30 from the center can be determined by means of position-measuring elements 34.

A method, which is characterized in the adjustment of the position of a susceptor 3 relative to a reactor housing 1 or a component 21 arranged in the reactor housing 1, wherein a flow-through area 10 extends between an outer periphery 4 of the susceptor 3 and an inner periphery 2 of the reactor housing 1 or the component 21, wherein the distance S between the outer periphery 4 and the inner periphery 2 is determined by means of a measuring device 25 and the position of the susceptor 3 relative to the inner periphery 2′ is adjusted with the aid of adjusting means 13, 14, 16, wherein the measuring device 25 is separably fastened on the susceptor 3 at a predetermined location with a central element 26, and wherein the inner periphery 2 of the reactor housing 1 or a component 21 arranged in the reactor housing 1 is scanned with sensing sections 30 formed on sensing arms 29, which protrude from the central element 26 beyond the outer periphery 4 of the susceptor 3.

A method, which is characterized in that the sensing sections 30 respectively have a sloping flank 31, which is acted upon by the inner periphery 2 of the reactor housing 1 or by the component 21 arranged in the reactor housing 1 as the opened reactor housing 1 is closed such that the sensing arms 29 are displaced in the direction of a center of the susceptor 3, and in that the distances of the sensing sections 30 from the center are determined by means of position-measuring elements 34.

A method, which is characterized in that the data on the position of the susceptor 3 determined by the measuring device is wirelessly transmitted through the wall of the reactor housing 1 with the aid of communication means.

A method, which is characterized in that the measuring device is supplied with power by a battery.

A method, which is characterized in that the position of the susceptor 3 is varied while the reactor housing 1 is closed and at a reduced total pressure within the reactor housing 1 and/or at an elevated temperature of the susceptor 3.

A method, which is characterized in that the position of the susceptor (3) is centered in that way that a gas flow above the susceptor or the lateral uniformity of a layer grown on one or more substrates located on the susceptor (3) is maximized.

A method, which is characterized in that after centering the susceptor (3) the lateral uniformity is further maximized by a flow of a flushing gas through a flushing gas opening (18) into the area located between the outer periphery (4) and the inner periphery (2).

A method, which is characterized in that after centering the susceptor (3) the uniformity is further maximized by varying the heat power of at least two heat elements (19, 20) for heating the susceptor (3).

List of Reference Symbols

| | |
|---|---|
| 1 | Reactor housing |
| 1′ | Upper housing part |
| 1″ | Lower housing part |
| 2 | Inner periphery/inner wall |
| 2′ | Inner periphery |
| 3 | Susceptor |
| 4 | Outer periphery |
| 5 | Substrate |
| 6 | Gas inlet element/showerhead |
| 7 | Gas discharge opening |
| 8 | Gas suction opening |
| 9 | Process chamber |
| 10 | Flow-through area |
| 11 | Housing section |
| 12 | Susceptor carrier |
| 13 | Flange |
| 13′ | Flange face |
| 14 | Flange |
| 14′ | Flange face |
| 15 | Bellows |
| 16 | Adjusting means/screw |
| 16′ | End face |
| 17 | Flushing gas duct |
| 18 | Flushing gas opening |
| 19 | Radially outer heater |
| 20 | Radially inner heater |
| 21 | Component |
| 22 | Peripheral edge |
| 23 | Spring |
| 24 | Collar |
| 25 | Measuring device |
| 26 | Central element |
| 27 | Centering pin |
| 28 | Centering opening |
| 29 | Sensing arm |
| 30 | Sensing section |
| 31 | Sloping flank |
| 32 | Measuring unit |
| 33 | Spring element |
| 34 | Position-measuring element |
| 35 | Communication device |
| 36 | Threaded bore |
| P | Arrow |
| S | Gap width |

1. A measuring device for determining a position of a susceptor (3) in a reactor housing (1), the measuring device comprising:
a central element (26), which is fastened on the susceptor (3) at a predefined location; and
a plurality of sensing arms (29), which protrude from the central element (26) beyond an outer periphery (4) of the susceptor (3), wherein said sensing arms respectively include a sensing section (30) that is brought in touching contact with a contact zone.

2. The measuring device of claim 1, wherein the contact zone is formed by an inner periphery (2) of the reactor housing (1) or a component (21) arranged in the reactor housing (1).

3. The measuring device of claim 1, wherein the central element (26) includes centering means (27, 28) which fasten the central element (26) on the susceptor (3), and wherein the predefined location is a center of the susceptor (3).

4. The measuring device of claim 1, further comprising communication means configured to wirelessly transmit data through a wall of the reactor housing (1).

5. The measuring device of claim 4, further comprising a battery configured to provide power to the communication means.

6. The measuring device of claim 1, further comprising spring elements (33) which act upon the sensing arms (29) in a direction extending away from the central element (26).

7. The measuring device of claim 1, further comprising position-measuring elements (34) which are configured to determine the respective positions of the sensing arms (29) relative to the central element (26).

8. The measuring device of claim 7, wherein the position-measuring elements (34) are configured to determine respective distances of the sensing sections (30) from a center of the measuring device.

9. The measuring device of claim 2, wherein each of the sensing sections (30) includes a sloping flank (31).

10. The measuring device of claim 9, wherein the sloping flanks (31) of the sensing sections (30) are arranged in such a way that the sloping flanks (31) are acted upon by the inner periphery (2) of the reactor housing (1) or by the component (21) arranged in the reactor housing (1) as the opened reactor housing (1) is closed and the sensing arms (29) are displaced toward a center of the susceptor (3) due to a sliding motion of the inner periphery (2) of the reactor housing (1) or the component (21) along the sloping flanks (31), wherein the respective distances of the sensing sections (30) from the center of the susceptor (3) are determined by means of position-measuring elements (34).

11. A method for adjusting a position of a susceptor (3) relative to a reactor housing (1) or a component (21) arranged in the reactor housing (1), wherein a flow-through area (10) extends between a gap between an outer periphery (4) of the susceptor (3) and an inner periphery (2) of the reactor housing (1) or the component (21), the gap defined by a gap width (S), the method comprising:
fastening a measuring device (25) on the susceptor (3) at a predetermined location on the susceptor (3), the measuring device fastened with a central element (26);
scanning the inner periphery (2) of the reactor housing (1) or the component (21) with sensing sections (30) formed on sensing arms (29) that protrude from the central element (26) beyond the outer periphery (4) of the susceptor (3);
determining, using the measuring device (25), the gap width (S); and
adjusting, using adjusting means (13, 14, 16), the position of the susceptor (3), thereby adjusting the gap width (S).

12. The method of claim 11, further comprising:
closing the reactor housing (1) which causes the inner periphery (2) of the reactor housing (1) or the component (21) arranged in the reactor housing (1) to act upon sloping flanks (31) of the sensing sections (30), which in turn causes the sensing arms (29) to be displaced towards a center of the susceptor (3); and
determining, using position-measuring elements (34), the respective distances between the sensing sections (30) from the center of the susceptor (3).

13. The method of claim 12, further comprising wirelessly transmitting, via communication means, data regarding the position of the susceptor (3), as determined by the measuring device (25).

14. The method of claim 13, further comprising providing power to the communication means from a battery.

15. The method of claim 11, wherein the position of the susceptor (3) is adjusted while the reactor housing (1) is closed and at a reduced total pressure within the reactor housing (1) and/or at an elevated temperature of the susceptor (3).

16. A method for adjusting a position of a susceptor (3) relative to a reactor housing (1) or a component (21) arranged in the reactor housing (1), wherein a flow-through area (10) extends between an outer periphery (4) of the susceptor (3) and an inner periphery (2) of the reactor housing (1) or the component (21), the method comprising:
adjusting with adjusting means (13, 14, 16) the position of the susceptor (3) relative to the inner periphery (2) so as to maximize a lateral uniformity of a gas flow above the susceptor or of a layer grown on one or more substrates lying on the susceptor (3).

17. The method of claim 16, wherein adjusting the position of the susceptor comprises:
adjusting, in a first adjusting step, the position of the susceptor (3) while the reactor housing (1) is open; and
adjusting, in one or more second adjusting steps, the position of the susceptor (3) while the reactor housing (1) is closed, the first adjusting step and the one or more second adjusting steps maximizing a lateral uniformity of the layer grown on the one or more substrates lying on the susceptor (3).

18. The method of claim 17, further comprising:
varying, in a third adjusting step, a flow of a flushing gas from several flushing gas openings (18) arranged circumferentially around the susceptor (3) into the flow-through area (10) while the reactor housing (1) is closed, the varying of the flow of the flushing gas further maximizing the lateral uniformity of the layer.

19. The method of claim 18, further comprising:
varying, in a fourth adjusting step, a heating power of at least two heating elements (19, 20) for heating the susceptor (3) while the reactor housing (1) is closed.

20. The method of claim 19, wherein one or more of the second, third and fourth adjusting steps are carried out at an elevated temperature and at a reduced pressure in the reactor housing (1).

21. The method of claim 20, further comprising measuring a thickness of the layer or a composition of the layer in situ at different circumferential positions of the susceptor (3) during one or more of the second, third and fourth adjusting steps.

22. The method of claim 21, further comprising repeatedly:
(i) measuring properties of the layer on a peripheral portion of the susceptor (3) at the different circumferential positions of the susceptor (3); and
(ii) performing one or more of the second, third and fourth adjusting steps.
